(19) United States
(12) Patent Application Publication
(10) Pub. No.: US 2003/0162363 A1
(43) Pub. Date: Aug. 28, 2003

(54) HDP CVD process for void-free gap fill of a high aspect ratio trench

(76) Inventor: Hua Ji, San Jose, CA (US)

Correspondence Address: Alan H MacPherson, MacPherson Kwok Chen & Heid LLP, 2402 Michelson Drive, Suite 210, Irvine, CA, 92612, US

(21) Appl. No.: 10/080,468

(22) Filed: Feb. 22, 2002

(51) Int. Cl. H01L 21/76

(52) U.S. Cl. 438/424

(57) ABSTRACT

High aspect ratio gaps on a substrate are filled using high density plasma chemical vapor deposition with a minimized ratio of an oxygen-containing component to a silicon-containing component or a minimized flow rate of the oxygen-containing component. Such minimization allows for reduced redeposition rates and reduced etch-to-deposition ratios, thereby increasing gap-fill capability. Consequently, gaps with aspect ratios of 4.0:1 and higher can be filled without the formation of voids associated with conventional methods.

### BACKGROUND

1. Field of the Invention

This invention generally relates to methods of thin film deposition and, more particularly, to a method of filling high aspect ratio gaps in and on substrates.

2. Description of Related Art

As semiconductor technology advances, circuit elements and interconnections on wafers or silicon substrates become increasingly dense. In order to prevent unwanted interactions between these circuit structures, insulator-filled gaps or trenches are provided between the circuit structures to physically and electrically isolate the elements and conductive lines. However, as circuit densities continue to increase, the widths of these gaps decrease, thereby increasing gap aspect ratios (AR), typically defined as the gap height divided by the gap width. As a result, filling these narrower gaps becomes more difficult, which can lead to unwanted voids and discontinuities in the insulating or gap-fill material.

Currently, high density plasma (HDP) oxide deposition is used to fill high aspect ratio gaps. Typical HDP deposition processes employ chemical vapor deposition (CVD) with a gas mixture containing oxygen, silane, and inert gases, such as argon, to achieve simultaneous dielectric etching and deposition. In an HDP CVD process, an RF bias is applied to a wafer substrate in a reaction chamber. Some of these gas molecules (particularly argon) are ionized in the plasma and accelerate toward the wafer surface when the RF bias is applied to the substrate. Material on the wafer is thereby sputtered (i.e., removed) when the heavy ions strike the surface. As a result, dielectric material deposited on the wafer surface is simultaneously sputter etched (i.e., removed) to help keep gaps open during the deposition process.

FIGS. 1A-1D illustrate, in more detail, the simultaneous etch and deposition process described above. In FIG. 1A, a dielectric material such as silicon dioxide (SiO₂), formed from silane (SiH₄) and oxygen (O₂), begins depositing on the surface of a wafer 100 to fill a gap 110 between circuit elements 120. In FIG. 1B, as the SiO₂ is being deposited, charged ions impinge on the SiO₂ or dielectric layer 125, thereby simultaneously etching the SiO₂ layer. 45° facets 130 inherently form at the corners of elements 120 during the deposition process because the etch rate at about 45° is approximately three to four times that on the horizontal surface. FIGS. 1C and 1D show the process continuing to fill gap 110 with simultaneous etching and deposition of SiO₂.

The relationship between the concurrent dielectric layer deposition and etching that occurs in the HDP CVD process can be expressed as an etch-to-deposition (E/D) ratio. In FIGS. 1A-1D, the E/D ratio is optimized such that facets 130 remain at the corners of circuit elements 120 throughout the HDP CVD process. However, as shown in FIG. 2, if the E/D ratio is decreased, facets 130 begin moving away from the corners of elements 120, and cusps 210 begin to form on sidewalls of gap 110 because the etching rate is not high enough to keep the gap open for filling. At a certain point in the process, cusps 210 will meet and prevent further deposition below the cusps. When this occurs, a void 320 is created in dielectric layer 125, as shown in FIG. 3.

Redeposition of sputtered material also occurs when dielectric material is etched. Redeposition occurs by two main mechanisms: backscattering from the ambient above the substrate and hitting an element on the substrate in a line-of-sight path. Some of the etched SiO₂ is redeposited on opposing surfaces through these two mechanisms, even though most of the etched SiO₂ is emitted back into the plasma and pumped out of the reaction chamber. As the distance between opposing surfaces decreases, redeposition increases.

By optimizing the E/D ratio, gaps with aspect ratios of up to about 3.0:1 can be filled without voids. However, this process approach has its limitations. As shown in FIG. 4, filling higher aspect ratio gaps results in voids 410 due to cusps 420 prematurely closing the gaps. As discussed above, this is due mainly to the shortened line-of-sight path between opposing sidewalls for higher aspect ratio gaps.

Therefore, with circuit densities increasing, higher aspect ratio gaps need to be filled without the void formation associated with current HDP CVD processes.

### SUMMARY

In accordance with the present invention, a method is provided for filling high aspect ratio gaps using high density plasma chemical vapor deposition processes with improved gap-filling capability.

In one aspect of the invention, a method for filling gaps during integrated circuit fabrication comprises providing a gas mixture comprised of silicon-containing, oxygen-containing, and inert components; selecting a flow rate of said silicon-containing component; minimizing a ratio of said oxygen-containing component to said silicon-containing component, wherein said minimized ratio allows formation of a film comprising a selected stoichiometry; and depositing said film over said gaps by using said gas mixture for simultaneous high density plasma chemical vapor deposition and sputter etching.

In another aspect of the present invention, a method for filling gaps during integrated circuit fabrication comprises providing a gas mixture comprised of silicon-containing, oxygen-containing, and inert components; selecting a flow rate of said silicon-containing component; minimizing a flow rate of said oxygen-containing component to allow formation of a film comprising a selected stoichiometry; and depositing said film over said gaps by using said gas mixture for simultaneous high density plasma chemical vapor deposition and sputter etching.

Advantageously, the present invention provides for gap filling of high aspect ratio trenches without the void formation associated with conventional HDP CVD processes. Further, the present invention reduces costs of integrated circuit fabrication by not requiring an upgrade of processing equipment.

These and other features and advantages of the present invention will be more readily apparent from the detailed description of the embodiments set forth below taken in conjunction with the accompanying drawings.

### BRIEF DESCRIPTION OF THE DRAWINGS

FIGS. 1A through 1D are sequential views of a conventional HDP CVD process with optimized E/D ratios;

FIG. 2 is a picture of cusp formation using a conventional HDP process;

FIG. 3 is a picture of void formation when filling a gap with an insufficient etching rate;

FIG. 4 is a picture of void formation when filling a high aspect ratio gap using a conventional HDP process;

FIG. 5 is a graph of the relationship between silane flow and the minimum oxygen to silane ratio previously used in the art.

FIG. 6 is a graph of the relationship between silane flow and minimized oxygen to silane ratio in accordance with one aspect of the present invention.

FIG. 7 is a graph of the relationship between silane flow and minimized oxygen flow in accordance with another aspect of the present invention.

FIGS. 8A through 8D are sequential views of high aspect ratio gaps filled using a method in accordance with one embodiment of the present invention;

FIG. 9 is a scanning electron microscope (SEM) picture of a high aspect ratio gap filled using conventional HDP CVD processes;

FIG. 10 is a SEM picture of a high aspect ratio gap filled using a method in accordance with one embodiment of the present invention; and

FIG. 11 is a SEM picture of a 4.3:1 aspect ratio gap filled using a method in accordance with another embodiment of the present invention.

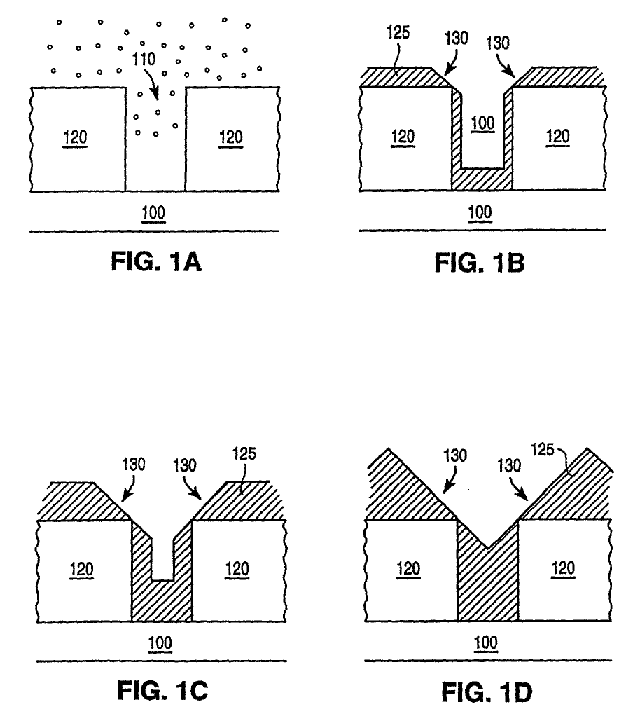

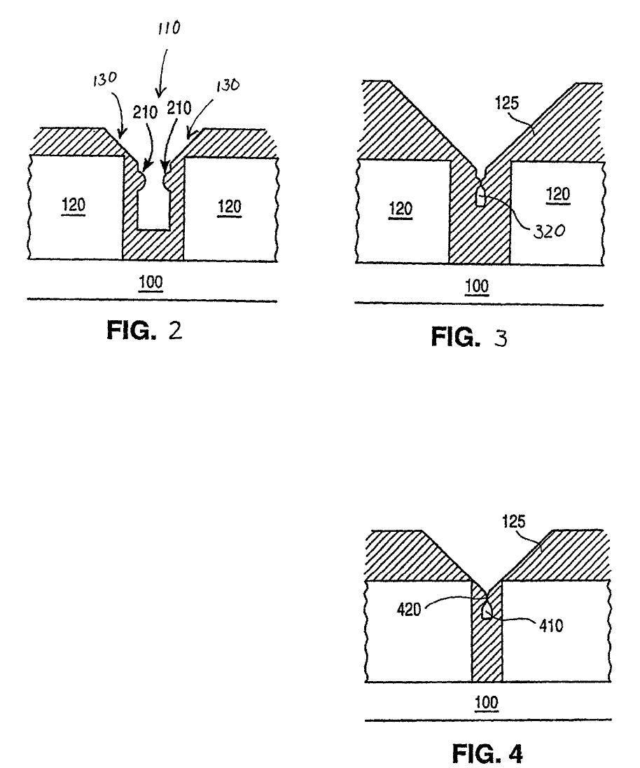

The use of similar reference numerals in different figures indicates similar or identical items.

### DETAILED DESCRIPTION

In accordance with an embodiment of the present invention, a method using high density plasma chemical vapor deposition (HDP CVD) with a minimized ratio of oxygen-containing components to silicon-containing components in a gas mixture is provided. Such a minimized ratio results in a minimization of redeposition and allows high aspect ratio gaps to be filled without voids associated with conventional methods.

In one embodiment, the method of the present invention is used in forming a shallow trench isolation (STI) structure, in which large numbers of small, closely spaced transistors are isolated from each other by filling gaps with a dielectric layer. The highest aspect ratios (AR>3.0:1) are associated with the STI structure. The method of the present invention may also be used in the formation of other layers during the fabrication of integrated circuits, such as pre-metal dielectric (PMD) layers.

Conventional HDP CVD processes utilize a gas mixture including a silicon-containing component, such as silane (SiH₄), an oxygen-containing component, such as oxygen gas (O₂), and an inert gas, such as argon (Ar), to simultaneously deposit and etch dielectric material, where SiH₄ and O₂ are used to form SiO₂ for the deposition component, and O₂ and Ar are used for the sputter etch component. In one embodiment of the present invention, SiH₄ and O₂ are used in the gas mixture but Ar is not used as the inert component. Instead, a low atomic weight inert gas lighter than Ar, such as helium (He) or neon (Ne), is used in the gas mixture to meet minimum process pressure constraints. Reducing process pressure below a minimum level may create particulate problems during deposition of the dielectric layer. Ar or heavier inert gases, such as Kr and Xe, are not included in the etch mixture in order to achieve better process control through lower etching rates. Thus, with the use of He as the inert component, oxygen becomes the main sputter etch component in the gas mixture in one embodiment. These gases are not limiting, and other suitable gases may be used as sources of silicon and oxygen. In another embodiment, the gas mixture may include the silicon-containing component and the oxygen-containing component but exclude the inert gas. The inert gas may be excluded when the particle issue is not of concern or when the process chamber is designed to keep process pressure at or above the minimum level.

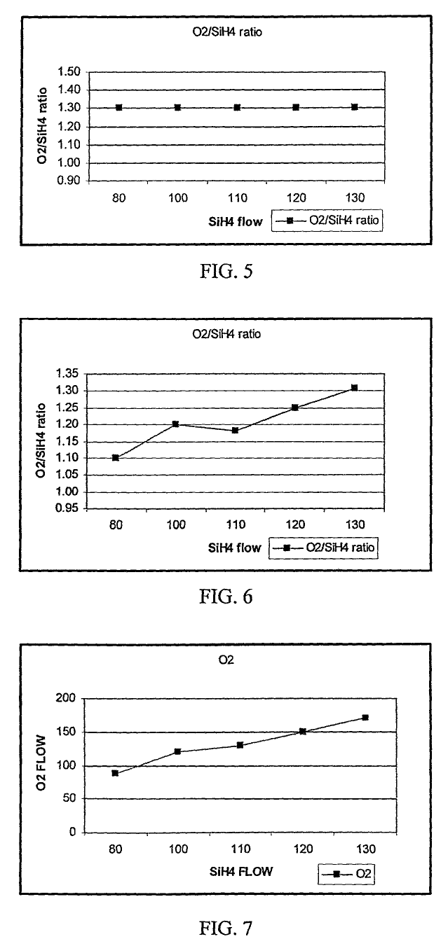

Etch and deposition rates associated with HDP CVD processes have typically been controlled by varying the flow rate of source gases, which affect the deposition rate, or by varying either the power supplied to the wafer for biasing or the flow rate of the inert gases, which affect the sputter etch rate. Typical oxygen flow rates for HDP CVD processes have ranged from about 170 sccm to about 375 sccm and typical silane flow rates for HDP CVD processes have ranged from about 130 sccm to about 150 sccm. Typical ratios of oxygen to silane for HDP CVD processes have ranged from 1.3 to 2.5 to provide what was believed to be the necessary stoichiometry for the formation of standard silicon dioxide dielectric layers. Accordingly, as shown in FIG. 5, the minimum oxygen to silane ratio has previously been at or above a floor of 1.3 in order to avoid formation of silicon-rich SiO₂ layers.

Contrary to conventional HDP CVD processes, in one embodiment of the present invention, the minimized ratio of the oxygen flow rate to the silane flow rate is provided below the previous 1.3 floor used in the art, as shown in FIG. 6. As silane flow is reduced, the minimum flow of oxygen required to form a standard dielectric layer with a selected refractive index, for example 1.46, is also reduced, as shown in FIG. 7. Accordingly, the minimized ratio of oxygen to silane below the previous floor of 1.3 allows for a reduced use of oxygen for a given silane flow, while maintaining the required stoichiometry for a standard dielectric gap fill layer or film. Further, a reduced flow rate of silane will further reduce the minimum amount of oxygen required for formation of the standard dielectric layer. Advantageously, the reduced flow rate or concentration of oxygen required for a selected flow rate or concentration of silane reduces the main sputtering component of the gas mixture, resulting in a reduction of sidewall redeposition, thereby helping to keep the gap open for filling.

In addition to a reduced oxygen to silane ratio, the method of the present invention allows for low etch-to-deposition (E/D) ratios, corresponding to greater gap-fill capability. An E/D ratio is defined by the equation:

E/D=(UBUC−BUC)/UBUC

where UBUC is the deposition rate of the process with no wafer bias or clamping (unbiased, unclamped), and BUC is the deposition rate of the process with wafer bias and no clamping (biased, unclamped). In one embodiment of the present invention, as the minimized oxygen to silane ratio is used to minimize the oxygen flow rate and to reduce the silane flow rate for depositing a dielectric layer, E/D ratios have also been reduced. Reduced E/D ratios correspond to the overall sputtering rate decreasing, and the aspect ratio gapfill capability increasing. For example, E/D ratios from about 0.0 to about −0.05 have been achieved for void-free gap filling, where the UBUC refractive index ranges from about 1.5 to about 1.6.

In one embodiment of the present invention, the E/D ratio and the redeposition rate is further minimized by reducing wafer bias power, by increasing source power, and/or by decreasing process pressure. Reducing high frequency (HF) power for wafer biasing lowers the driving force applied to the wafer, reducing the sputtering rate and therefore reducing the redeposition rate. Increasing the low frequency (LF) power for plasma formation increases the plasma density, thereby reducing the sputtering rate and redeposition rate. Lowering of the process pressure can be achieved by reducing total gas flow or by increasing the speed at which the gases in the process chamber are pumped out. The reduction in process pressure reduces backscatter collisions in the ambient above the substrate and thereby reduces the redeposition rate. Advantageously, the embodiments of the present invention reduce the costs of integrated circuit fabrication by not requiring an upgrade of processing equipment.

Table 1 below provides process parameter ranges to fill a high aspect ratio gap (AR>3.0:1, width ˜0.1 micron) in one embodiment of the present invention, with the actual parameters being dependent upon the wafer size (e.g., 200 or 300 mm diameter). The gas mixture comprises silane and oxygen at a minimized ratio of oxygen to silane between about 1.0 and about 1.2. The silane flow rate is between about 70 sccm and about 90 sccm. Oxygen is at a minimized flow rate between about 72 sccm and about 105 sccm to form a silicon dioxide layer with a refractive index of 1.46. In this embodiment, helium is used to meet minimum process pressure constraints to avoid particle formation with a helium flow rate ranging between about 305 sccm and about 358 sccm. E/D ratios range from about 0.0 to about −0.05. LF power requirements for plasma formation range from about 4.2 kW to about 5.0 kW and HF power requirements for biasing the wafer range from about 1.0 kW to about 1.4 kW. Acceptable process pressure is between about 3.5 mTorr and about 5.5 mTorr.

TABLE 1

| Process Parameter | Range |
|---|---|
| Silane Flow Rate (sccm) | 70-90 |
| Oxygen Flow Rate (sccm) | 72-105 |
| Helium Flow Rate (sccm) | 305-358 |
| Oxygen/Silane Ratio | 1.0-1.2 |
| E/D Ratio | 0.0-(−0.05) |
| LE Power (kW) | 4.2-5.0 |
| HF Power (kW) | 1.0-1.4 |
| Process Pressure (mTorr) | 3.5-5.5 |

The HDP CVD process can be performed in conventional HDP CVD reactors, such as the standard Novellus HDP chamber (Concept 2 SPEED) of Novellus Systems, Inc. of San Jose, Calif. For example, in the Novellus reactor, LF power is applied to the dome of the reactor to create the background plasma, and HF power is applied to an electrostatic chuck or pedestal to attract ionized molecules in the plasma toward the wafer surface for sputtering. In one example, the volume of the HDP CVD chamber is 53 liters and the capacity of the pump for driving out plasma is 1,100 liters per second.

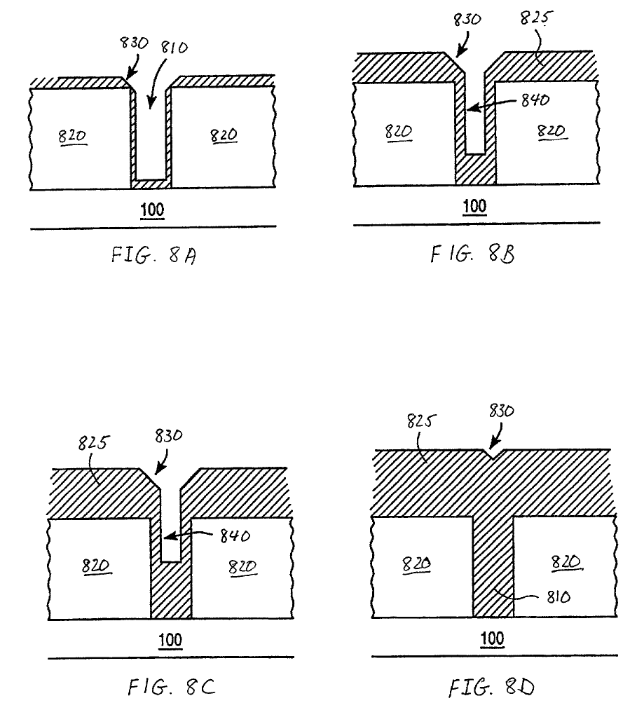

FIGS. 8A-8D illustrate how a high aspect ratio gap (AR>3.0:1) is filled without void formation in accordance with an embodiment of the present invention. In FIG. 8A, circuit elements 820 are formed on a substrate or wafer 100, creating gaps 810 therebetween. Circuit elements 820 can be, for example, transistors, conductors, or interconnects. A gap 810 with a high aspect ratio, typically greater than 3.0:1, is filled using HDP CVD with a minimized ratio of oxygen to silane and/or minimized oxygen flow for a selected silane flow rate. In one embodiment, He is used as the inert gas component and O₂ is used as the main etching component since He has a very low atomic weight and therefore only contributes negligibly to sputter etching.

During the initial stages of the process, 45° facets 830 form at the corners of circuit elements 820, as shown in FIG. 8A. Even though Ar or heavy inert gases, which have conventionally been used as the primary etchant, are eliminated in this embodiment of the present invention, ionized gases of O₂ will contribute to the etching component. However, because the main sputter etch component is reduced when O₂ is minimized, thereby reducing redeposition, facets 830 begin to move away from the corners of circuit elements 820 without cusp formation as more material deposits on the surfaces to form the SiO₂ or dielectric layer 825, as shown in FIGS. 8B and 8C.

Further, because a deposition source component is reduced when O₂ is minimized, much less material is available to redeposit on sidewalls 840 and facets 830, as shown in FIGS. 8B and 8C. As a result, cusp formation is further reduced, and facets move away more slowly from the corners of the circuit elements. Because there is very little sidewall deposition, which is mainly driven by redeposition, high aspect ratio gaps do not close prematurely even though the facets are moving away from the corners. FIG. 8D then shows high aspect ratio gap 810 filled without void formation.

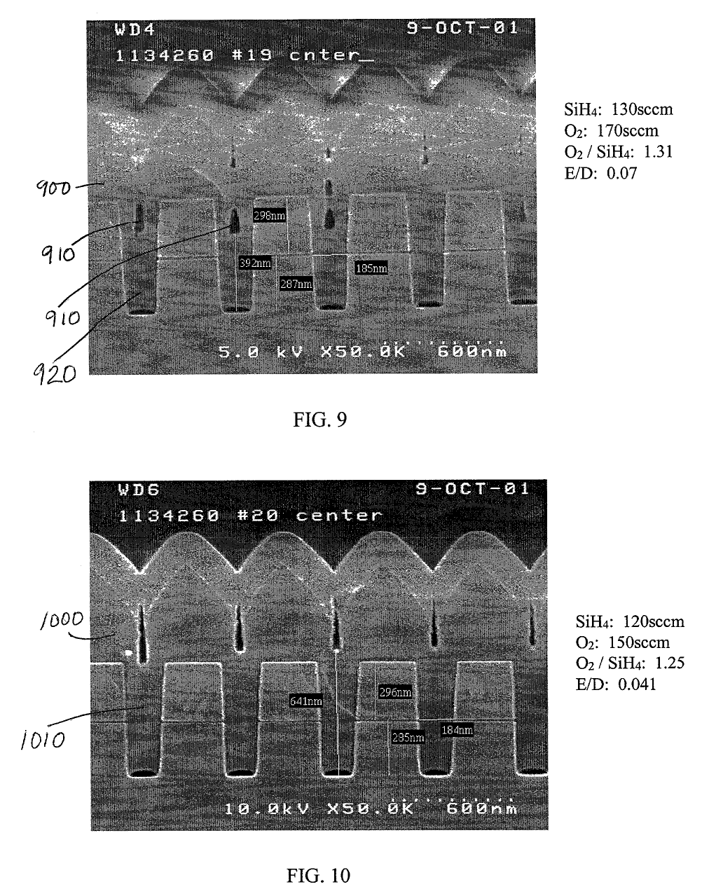

FIGS. 9 and 10 are scanning electron microscope (SEM) pictures of a high aspect ratio gap (AR>3.0:1) filled using a conventional HDP CVD process and using a method of the present invention, respectively. FIG. 9 shows voids 910 formed in dielectric layer 900 within gaps 920, while FIG. 10 shows void-free gaps 1010 filled with dielectric layer 1000.

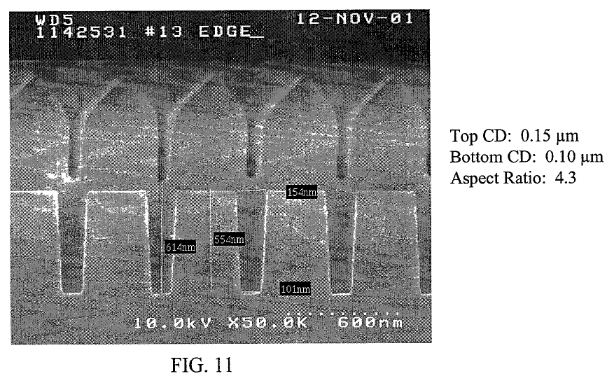

In accordance with the present invention, gaps with aspect ratios over 4.0:1 and with widths of 0.1 micron have been filled without the formation of voids. In one example, as shown in FIG. 11, gaps with an aspect ratio of about 4.3, top width of about 0.15 μm, and bottom width of about 0.10 μm, have been filled without the formation of voids in the gaps or damage to the circuit elements. Therefore, by minimizing the O₂/SiH₄ ratio and the flow rates of oxygen and silane below conventional thresholds, void-free gap fill is possible at higher aspect ratios (AR>3.0:1) than is possible with conventional HDP CVD processes.

The above-described embodiments of the present invention are merely meant to be illustrative and not limiting. It will thus be obvious to those skilled in the art that various changes and modifications may be made without departing from this invention in its broader aspects. Therefore, the appended claims encompass all such changes and modifications as falling within the true spirit and scope of this invention.

We claim:

1. A method for filling gaps during integrated circuit fabrication, comprising:
providing a gas mixture comprised of silicon-containing and oxygen-containing components;
selecting a flow rate of said silicon-containing component;
minimizing a ratio of said oxygen-containing component to said silicon-containing component, wherein said minimized ratio allows formation of a film comprising a selected stoichiometry; and
depositing said film over said gaps by using said gas mixture for simultaneous high density plasma chemical vapor deposition and sputter etching.

2. The method of claim 1, wherein said silicon-containing component comprises no more than 18% total concentration by volume of said gas mixture.

3. The method of claim 1, wherein said silicon-containing component is at a flow rate between about 70 sccm and about 90 sccm.

4. The method of claim 1, wherein said silicon-containing component comprises silane.

5. The method of claim 1, wherein said oxygen-containing component comprises no more than 21% total concentration by volume of said gas mixture.

6. The method of claim 1, wherein said oxygen-containing component is at a flow rate between about 72 sccm and about 105 sccm.

7. The method of claim 1, wherein said oxygen-containing component comprises O₂.

8. The method of claim 1, wherein said gas mixture is further comprised of an inert component.

9. The method of claim 8, wherein said inert component is at a flow rate between about 305 scam and about 358 sccm.

10. The method of claim 8, wherein said inert component comprises helium.

11. The method of claim 1, wherein said minimized ratio is below approximately 1.2.

12. The method of claim 1, wherein said minimized ratio is between about 1.0 and about 1.2.

13. The method of claim 1, wherein said gas mixture is at a pressure between about 3.5 mTorr and about 5.5 mTorr.

14. The method of claim 1, wherein said film is deposited over said gaps at an etch-to-deposition ratio between about 0.0 and about −0.05.

15. The method of claim 1, wherein said film comprises silicon oxide.

16. The method of claim 1, wherein said film comprises a refractive index of about 1.46.

17. The method of claim 1, further comprising:
providing a low frequency power source operable to form plasma from said gas mixture, said low frequency power source providing power at between about 4.2 kW and about 5.0 kW.

18. The method of claim 1, further comprising:
providing a high frequency power source operable to bias a substrate, said high frequency power source providing power at between about 1.0 kW and about 1.4 kW.

19. A method for filling gaps during integrated circuit fabrication, comprising:
providing a gas mixture comprised of silicon-containing and oxygen-containing components;
selecting a flow rate of said silicon-containing component;
minimizing a flow rate of said oxygen-containing component to allow formation of a film comprising a selected stoichiometry; and
depositing said film over said gaps by using said gas mixture for simultaneous high density plasma chemical vapor deposition and sputter etching.

20. The method of claim 19, wherein said silicon-containing component is at a flow rate between about 70 sccm and about 90 sccm.

21. The method of claim 19, wherein said silicon-containing component comprises silane.

22. The method of claim 19, wherein said oxygen-containing component is at a flow rate between about 72 sccm and about 105 sccm.

23. The method of claim 19, wherein said oxygen-containing component comprises O₂.

24. The method of claim 19, wherein said gas mixture is further comprised of an inert component.

25. The method of claim 24, wherein said inert component is at a flow rate between about 305 sccm and about 358 sccm.

26. The method of claim 24, wherein said inert component comprises helium.

27. The method of claim 19, wherein a ratio of said oxygen-containing component to said silicon-containing component is below approximately 1.2.

28. The method of claim 19, wherein a ratio of said oxygen-containing component to said silicon-containing component is between about 1.0 and about 1.2.

29. The method of claim 19, wherein said film is deposited over said gaps at an etch-to-deposition ratio between about 0.0 and about −0.05.
